(19) United States
(12) Patent Application Publication
(10) Pub. No.: US 2008/0063131 A1
(43) Pub. Date: Mar. 13, 2008

(54) Phase-locked loop circuit

(75) Inventor: Manabu Furuta, Kanagawa (JP)

Correspondence Address: FOLEY AND LARDNER LLP;SUITE 500, 3000 K STREET NW, WASHINGTON, DC, 20007, US

(73) Assignee: NEC Electronics Corporation

(21) Appl. No.: 11/892,706

(22) Filed: Aug. 27, 2007

(30) Foreign Application Priority Data
Aug. 31, 2006 (JP) 2006-235193

(51) Int. Cl. H03D 3/24

(52) U.S. Cl. 375/376

(57) ABSTRACT

A phase-locked loop circuit includes a phase detector detecting a phase difference between a first clock and a second clock; a voltage controlled oscillator outputting the second clock based on an input voltage that fluctuates corresponding to the phase difference detected by the phase detector; and a selector selecting the first clock from a plurality of clocks based on a clock change signal that is transmitted to the selector while the input voltage is set substantially constant.

### BACKGROUND OF THE INVENTION

1. Field of the Invention

This invention relates to a phase-locked loop circuit.

2. Description of Related Art

From past to now, a phase-locked loop circuit (hereinafter referred to as a PLL circuit), which generates an output clock synchronized with an input clock, has widely been known.

Japanese Unexamined Patent Application Publication No. 2001-94420 discloses a PLL circuit that comprises a selector for selecting one input clock from a plurality of clocks.

Above-mentioned PLL circuit disclosed in the Japanese Unexamined Patent Application Publication No. 2001-94420 is shown in FIG. 8. As shown in FIG. 8, the PLL circuit 100 includes a selector 101, a 1/M divider (1/M DIV) 102, a phase detector (PD) 103, a loop filter (LF) 104, a voltage controlled oscillator (VCO) 105, a 1/M divider (1/M DIV) 106, a 1/L fixed divider (1/L DIV) 107, and a control circuit 108.

Based on a system-change signal input via a port 3 (P3), the selector 101 selects a clock f1 or clock f2 as an input clock, then the selector 101 outputs the selected clock to the 1/M divider 102. Incidentally, the clock f1 is input to the selector 101 via a port 1 (P1) and the clock f2 is input to the selector 101 via a port 2 (P2).

The input clock is divided in frequency by the 1/M divider 102, and then input to the PD 103. An output clock divided in frequency by each of the 1/L divider 107 and 1/M divider 106 is also input to the PD 103. The PD 103 compares the two clocks and detects a phase difference between the two clocks. Then a phase difference signal is output from the PD 103 to the LF 104. Alternating component included in the phase difference signal is removed by the LF 104. Then the phase difference signal is input to the VCO 105. A frequency of the output clock output from VCO 105 is determined based on the voltage level of the phase difference signal input to the VCO 105.

As shown in FIG. 8, the system-change signal input via a port 3 is transferred to the control circuit 108 in addition to the selector 101 when a system of the PLL circuit 100 is to be changed. The control circuit 108 sets division ratios of the 1/M dividers 102 and 106 to be smaller than a predetermined division ratio immediately after the selector 101 changes the input clock based on the system-change signal. After that, 1/M dividers 102, 106, and 1/L divider 107 are reset and the division ratios of the 1/M dividers 102 and 106 are changed to other values.

In this way, it is possible to synchronize the output clock with a new input clock within a relatively short period of time, when the selector 101 changes the input clock.

However, the voltage input to the VCO 105 from the LF 104 is not controllable at the time the input clock is changed by the selector 101 in the Japanese Unexamined Patent Application Publication No. 2001-94420. More specifically, a phase difference between the two clocks input to the PD 103 is unknown at the time the input clock is changed by the selector 101. A voltage over a tolerance range could be input to the VCO 105, and a waveform of the output clock from the VCO 105 could be disturbed and a functioning of a circuit connected to the VCO 105 could also be disturbed.

As explained above, it was difficult to suppress the disturbance of the output clock effectively at the time of changing the input clock.

### SUMMARY

In one embodiment, a phase-locked loop circuit includes a phase detector detecting a phase difference between a first clock and a second clock; a voltage controlled oscillator outputting the second clock based on an input voltage that fluctuates corresponding to the phase difference detected by the phase detector; and a selector selecting the first clock from a plurality of clocks based on a clock change signal that is transmitted to the selector while the input voltage is set substantially constant.

In another embodiment, a phase-locked loop circuit includes a selector selecting a first clock from a plurality of clocks based on a clock change signal; a first divider dividing the first clock in frequency; a second divider dividing a second clock in frequency; a phase detector detecting a phase difference between a clock output from the first divider and a clock output from the second divider; a voltage controlled oscillator outputting the second clock based on an input voltage that fluctuates corresponding to the phase difference detected by the phase detector; and a control circuit setting the input voltage substantially constant and outputting the clock change signal while the input voltage is set substantially constant.

In still another embodiment, a phase-locked loop circuit includes a phase detector detecting a phase difference between a first clock and a second clock; a voltage controlled oscillator outputting the second clock based on an input voltage that fluctuates corresponding to the phase difference detected by the phase detector; a selector selecting the first clock from a plurality of clocks based on a clock change signal; and means for setting the input voltage substantially constant and for outputting the clock change signal while the input voltage is set substantially constant.

According to this invention, it is possible to suppress the disturbance in the waveform of the output clock effectively at the time of changing the clock by the selector.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a schematic block diagram to describe a configuration of a PLL circuit according to a first embodiment of the present invention;

FIG. 2 is a chart to explain an operation of a charge pump circuit according to the first embodiment;

FIG. 3 is a timing chart to describe an operation of the PLL circuit according to the first embodiment;

FIG. 4 is a schematic circuit diagram to describe a configuration of a PLL circuit according to a second embodiment of the present invention;

FIG. 5 is a timing chart to describe an operation of the PLL circuit according to the second embodiment;

FIG. 6 is a schematic block diagram to describe a configuration of a PLL circuit according to a third embodiment of the present invention;

FIG. 7 is a timing chart to describe an operation of the PLL circuit according to the third embodiment; and

FIG. 8 is a schematic block diagram to describe a configuration of a conventional PLL circuit.

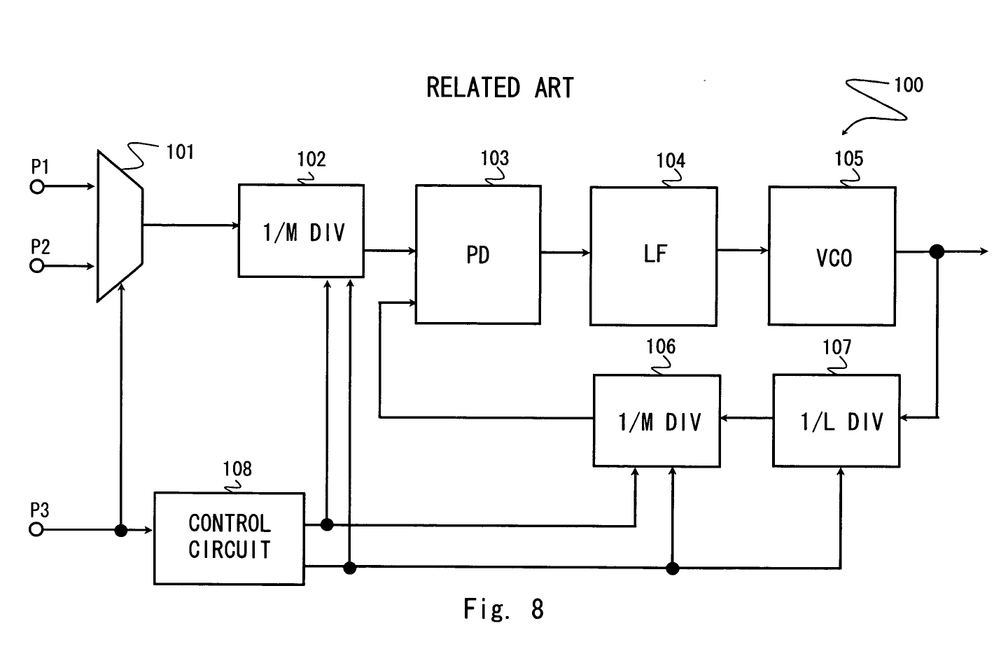

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

### First Embodiment

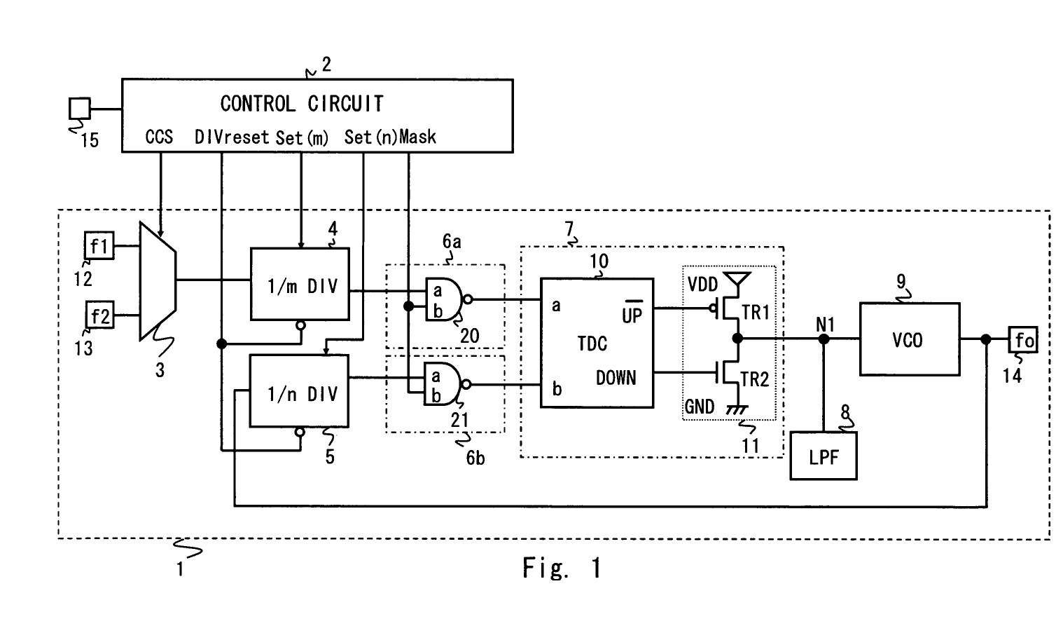

FIG. 1 shows a schematic block diagram of a phase-locked loop circuit (PLL circuit) 1. A control circuit 2 is also shown in FIG. 1.

As shown in FIG. 1, the PLL circuit 1 includes a selector 3, a 1/m divider (1/m DIV) 4 (note that m is nonnegative integer), a 1/n divider (1/n DIV) 5 (note that n is nonnegative integer), switch circuits 6a and 6b, a phase detector (PD) 7, a low-pass filter circuit (LPF) 8, and a voltage controlled oscillator (VCO) 9. The PD 7 includes a timing detection circuit (TDC) 10 and a charge pump circuit (charge pump) 11.

The PLL circuit 1 operates based on control signals (CCS (Clock Change Signal), DIVreset, Set(m), Set (n), Mask) from the control circuit 2. The control circuit 2 generates the control signals (CCS, DIVreset, Set(m), Set(n), Mask) based on a system-change signal (SC-signal) input via a control terminal 15. The control signals (CCS, DIVreset, Set(m), Set(n), Mask) are transmitted to the PLL circuit 1 from the control circuit 2 in a predetermined order and at a predetermined timing.

A clock f1 is input to the selector 3 via a first input port 12. A clock f2 is input to the selector 3 via a second input port 13. The selector 3 selects one input clock from the clock f1 and the clock f2 based on the control signal CCS. The selector 3 selects the clock f1 as the input clock when the control signal CCS is LOW. The selector 3 selects the clock f2 as the input clock when the control signal CCS is HIGH. The input clock selected by the selector 3 is transferred to the 1/m divider 4.

The selector 3 outputs the input clock. The input clock output from the selector 3 is transferred to the 1/m divider 4. The 1/m divider 4 divides the input clock in frequency, and outputs the clock divided in frequency (a first clock divided in frequency). The 1/m divider 4 is configured by a so-called counter.

Now, the 1/m divider 4 is reset based on the control signal DIVreset transmitted from the control circuit 2. The division ratio of the 1/m divider 4 is set based on the control signal Set (m) transmitted from the control circuit 2.

The 1/n divider 5 divides an output clock Fo in frequency and outputs the clock divided in frequency (a second clock divided in frequency). Note that, the output clock Fo is transferred from the VCO 9 to the 1/n divider 5. The 1/n divider 5 is configured by a so-called counter as well as the 1/m divider 4.

The division ratio of the 1/n divider 5 is reset based on the control signal DIVreset transmitted from the control circuit 2. The division ratio of the 1/n divider 5 is set based on the control signal Set(n) transmitted from the control circuit 2.

In this embodiment, the switch circuit 6a is provided between the 1/m DIV 4 and the timing detection circuit (TDC) 10. The switch circuit 6b is provided between the 1/n DIV 5 and the TDC 10.

By adopting this configuration, the disturbance in the output clock output from the VCO 9 is suppressed at the time of changing the input clock by the selector 3 for changing a system of the PLL circuit 1. This point will be explained below.

The switch circuit 6a is a NAND 20. The NAND 20 is a logic circuit having 2-input and 1-output terminals. An output terminal of the 1/m divider 4 is connected to an input terminal a of the NAND 20. The first clock divided in frequency by the 1/m divider 4 is transferred to the input terminal a of the NAND 20. An input terminal b of the NAND 20 is connected to the control circuit 2. The control signal Mask is transferred to the input terminal b of the NAND 20 from the control circuit 2.

Based on the control signal Mask transferred to the NAND 20 from the control circuit 2, an output status of the NAND 20 is determined. More specifically, when the control signal Mask is HIGH, the NAND 20 outputs an inverted clock against the first clock divided in frequency by the 1/m DIV 4. When the level of the control signal Mask is LOW, the NAND 20 outputs a constant high-level voltage signal.

That is, the switch circuit 6a selectively outputs the inverted clock or the constant high-level voltage signal to the PD 7 (an input terminal a of the TDC 10) based on the level of the control signal Mask transmitted from the control circuit 2.

A configuration of the switch circuit 6b is equal to the configuration of the switch circuit 6a. A NAND 21 of the switch circuit 6b corresponds to the NAND 20 of the switch circuit 6a.

Note that, an input terminal a of the NAND 21 is connected to an output terminal of the 1/n divider 5. A clock divided in frequency by the 1/n divider 5 is input to the input terminal a of the NAND 21. An input terminal b of the NAND 21 is connected to the control circuit 2. The control signal Mask is transferred to the input terminal b of the NAND 21 from the control circuit 2.

As well as the NAND 20, an output status of the NAND 21 is determined based on the control signal Mask transferred to the NAND 21 from the control circuit 2. More specifically, when the control signal Mask is HIGH, the NAND 21 outputs the inverted clock. When the control signal Mask is LOW, the NAND 21 outputs the constant high-level voltage signal.

That is, the switch circuit 6b selectively outputs the inverted clock or the constant high-level voltage signal to the PD 7 (an input terminal b of the TDC 10) based on the level of the control signal Mask transmitted from the control circuit 2.

As shown in FIG. 1, the phase detector 7 includes the TDC 10 and the charge pump 11.

The TDC 10 is a logic circuit having 2-input and 2-output terminals. An input terminal a of the TDC 10 is connected to the output terminal of the switch circuit 6a. An input terminal b of the TDC 10 is connected to the output terminal of the switch circuit 6b. An output terminal UP-bar of the TDC 10 is connected to a first control terminal (gate terminal of a P-type MOS (Metal Oxide Semiconductor) transistor TR1) of the charge pump 11. An output terminal DOWN of the TDC 10 is connected to a second control terminal (gate terminal of a N-type MOS (Metal Oxide Semiconductor) transistor TR2) of the charge pump 11.

The TDC 10 changes a level of a voltage signal that is output from the output terminal UP-bar of the TDC 10 at the time the TDC 10 detects a fall in a clock input to the input terminal a of the TDC 10. More specifically, the TDC 10 changes a level of the voltage signal (a first timing signal) from a higher level (HIGH) to a lower level (LOW), when the TDC 10 detects a fall in the clock input to the input terminal a of the TDC 10. The TDC 10 changes a level of a voltage signal that is output from the output terminal DOWN of the TDC 10 at the time the TDC 10 detects a fall in the clock input to the input terminal b of the TDC 10. More specifically, the TDC 10 changes a level of the voltage signal (a second timing signal) from LOW to HIGH, when the TDC 10 detects a fall in the clock input to the input terminal b of the TDC 10.

The charge pump 11 includes an inverter comprised of the P-type MOS transistor TR1 and the N-type MOS transistor TR2 which are connected in series. A source terminal of the TR1 is connected to a power supply potential (VDD). A gate terminal (a control terminal) of the TR1 is connected to the output terminal UP-bar of the TDC 10. A drain terminal of the TR1 is connected to a drain terminal of the TR2. A gate terminal (a control terminal) of the TR2 is connected to the output terminal DOWN of the TDC 10. A source terminal of the TR2 is connected to a ground potential (GND).

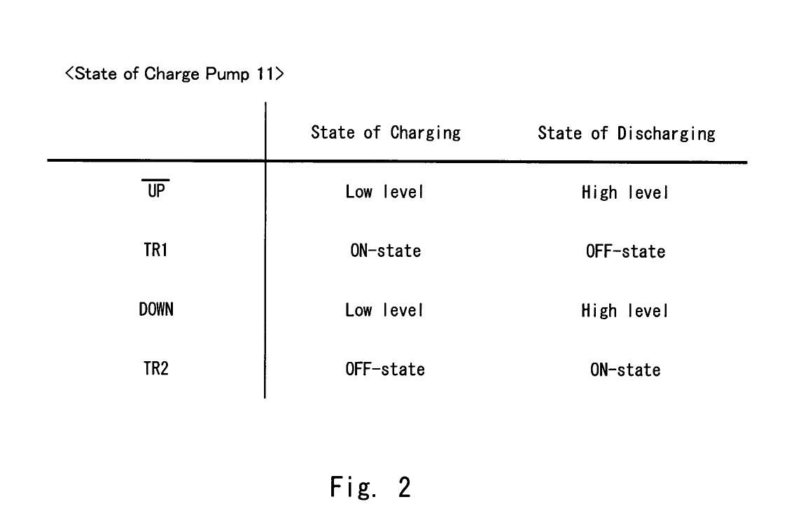

The charge pump 11 generates a current (phase difference current) that corresponds to a phase difference between the clock divided in frequency by the 1/m divider 4 and the clock divided in frequency by the 1/n divider 5. An operation of the charge pump 11 will be described below with reference to the FIG. 2.

As shown in FIG. 1, the LPF 8 is connected to a node N1 between the PD 7 and the VCO 9. The LPF 8 is configured to include at least one capacitor.

The capacitor included in the LPF 8 is charged or discharged corresponding to a current generated in the charge pump 11. An amount of the current generated in the charge pump 11 corresponds to a phase difference between the clock divided in frequency by the 1/m divider 4 and the clock divided in frequency by the 1/n divider 5 as mentioned above. A potential level of the node N1 is varied corresponding to a charge or a discharge of the capacitor included in the LPF 8. In this way, a frequency of the output clock output from the VCO 9 is regulated. Note that, an input voltage of the VCO 9 is equal to a voltage at the node N1.

As shown in FIG. 1, an input terminal of the VCO 9 is connected to the PD 7 and the LPF 8, and an output terminal of the VCO 9 is connected to an output terminal 14 and the input terminal of the 1/n divider 5. The output clock Fo output from the VCO 9 is transferred to the output terminal 14 and the input terminal of the 1/n divider 5.

The VCO 9 outputs the output clock Fo having a frequency corresponding to a voltage level of the input voltage that is input to the input terminal of the VCO 9. That is, a frequency of the output clock Fo becomes lower when the input voltage (a potential level of the node N1) becomes lower. A frequency of the output clock Fo becomes higher when the input voltage (a potential level of the node N1) becomes higher.

With reference to the FIG. 2, an operation of the charge pump 11 is described.

As shown in FIG. 2, the charge pump 11 is in a state of being charged when the first timing signal output from the output terminal UP-bar of the TDC 10 is LOW and the second timing signal output from the output terminal DOWN of the TDC 10 is LOW. That is, the TR1 is in on-state when the first timing signal is LOW, and the TR2 is in off-state when the second timing signal is LOW. A current is input from the charge pump 11 to the LPF 8. In other words, the capacitor included in the LPF 8 is charged by a current generated in the charge pump 11.

When the second timing signal changes to HIGH from LOW at this condition, the TDC 10 is in a reset state. So, a current, which is input to the LPF 8 from the charge pump 11 when the charge pump 11 is in a state of being charged, is set as a phase difference current that corresponds to a phase difference between the first clock divided in frequency by the 1/m divider 4 and the second clock divided in frequency by the 1/n divider 5. More specifically, the phase difference current reflects an amount of phase delay in the output clock Fo against the input clock selected by the selector 3.

As shown in FIG. 2, the charge pump 11 is in a state of being discharged when the first timing signal output from the output terminal UP-bar of the TDC 10 is HIGH and the second timing signal output from the output terminal DOWN of the TDC 10 is HIGH. That is, the TR1 is in off-state when the first timing signal is HIGH, and the TR2 is in on-state when the second timing signal is HIGH. A current is input from the LPF 8 to the charge pump 11. In other words, the capacitor included in the LPF 8 is discharged by a current generated in the charge pump 11.

When the first timing signal changes to a lower level at this condition, the TDC 10 is in a reset state. So, a current, which is input to the LPF 8from the charge pump 11 when the charge pump 11 is in a state of being discharged, is set as a phase difference current that corresponds to a phase difference between the first clock divided in frequency by the 1/m divider 4 and the second clock divided in frequency by the 1/n divider 5. More specifically, the phase difference current reflects an amount of phase lead in the output clock Fo against the input clock selected by the selector 3.

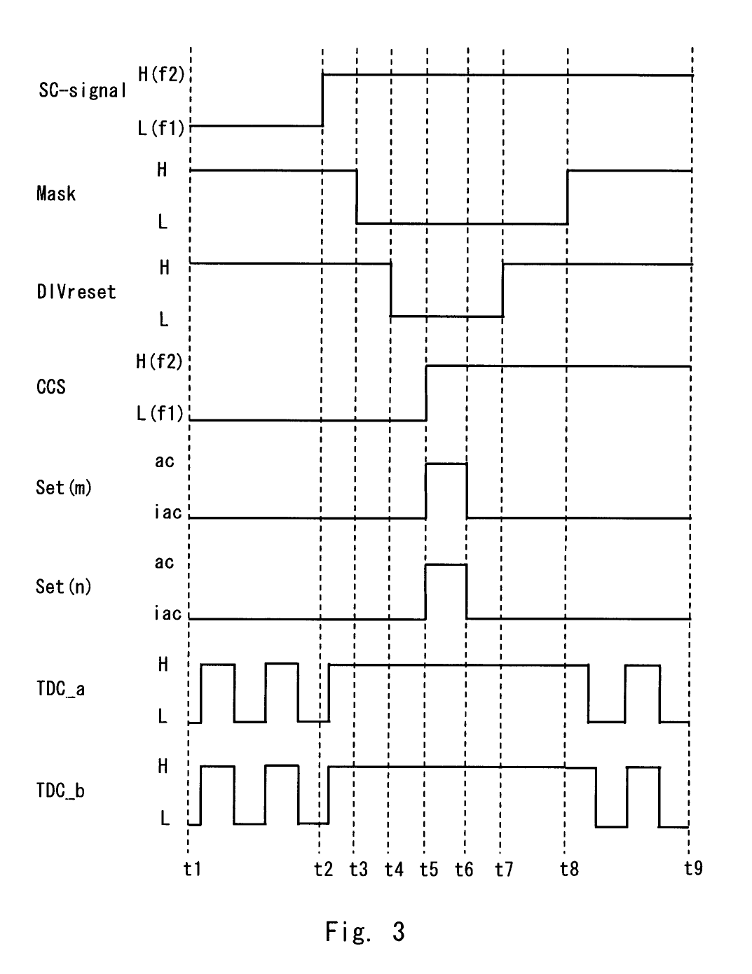

Now, a system change operation of the PLL circuit 1 is described with reference to the FIG. 3. The PLL circuit 1 changes the input clock based on the control signals transmitted from the control circuit 2 to the PLL circuit 1.

During a time of t1 to t2, which is the time before the system is changed, the first clock that is divided in frequency by the 1/m divider 4 and inverted by the switch circuit 6a is input to the input terminal a of the TDC 10. The second clock that is divided in frequency by the 1/n divider 5 and inverted by the switch circuit 6b is input to the input terminal b of the TDC 10.

At t2, the SC-signal changes from LOW to HIGH. The SC-signal is input to the control circuit 2 via the control terminal 15. The control circuit 2 generates the control signals (CCS, DIVreset, Set(m), Set(n), Mask) based on the SC-signal having a higher level. Note that the clock f2 is selected when the SC-signal is HIGH and the clock f1 is selected when the SC-signal is LOW.

At t3, the control signal MASK changes from HIGH to LOW. At this time, an output level of the switch circuit 6a is set to HIGH. And also, an output level of the switch circuit 6b is set to HIGH. The control signal Mask is set to LOW until t8.

The TDC 10 detects a fall in the clock input to the input terminal a of the TDC 10 and a fall in the clock input to the input terminal b of the TDC 10. The input voltages input to the input terminals a and b of the TDC 10 are set to a voltage signal having a higher level (a substantially constant voltage) as explained above. Thus, the voltage signal (the first timing signal) output from the output terminal UP-bar of the TDC 10 and the voltage signal (the second timing signal) output from the output terminal DOWN of the TDC 10 are fixed. More specifically, the first timing signal is set to a higher level and the second timing signal is set to a lower level. Both of the TR1 and TR2 of the charge pump 11 are in off-state.

Note that, the VCO 9 keeps on outputting the output clock Fo having a same frequency as that at t3. In other words, the VCO 9 is in a self-running state.

At t4, the control signal DIVreset, which is input to the 1/m divider 4 and the 1/n divider 5 from the control circuit 2, is set to LOW. The division value of the 1/m divider 4 and the 1/n divider 5 is reset based on the control signal DIVreset that is input to each of a reset terminal of the 1/m divider 4 and the 1/n divider 5. The division value of the 1/m divider 4 corresponds to a value of counter included in the 1/m divider 4. The division value of the 1/n divider 5 corresponds to a value of counter included in the 1/n divider 5. The control signal DIVreset is set to LOW until t7.

At t5, the control signal CCS, which is input to the selector 3 from the control circuit 2, changes to HIGH. The selector 3 changes the input clock from the clock f1 to the clock f2. The selector 3 outputs the selected clock f2 as an input clock.

Also at t5, the control signal Set (m) is input to the 1/m divider 4 from the control circuit 2. The control signal Set (m) is used to change the division ratio of the 1/m divider 4. At t5, the control signal Set (n) is input to the 1/n divider 5 from the control circuit 2. The control signal Set (n) is used to change the division ratio of the 1/n divider 5. These control signals Set (m) and Set (n) are set in an active state (ac) until t6. After t6 these control signals Set (m) and Set (n) are set in an inactive state (iac).

At t7, the control signal DIVreset changes to HIGH. Then, 1/m divider 4 and the 1/n divider 5 start counting at the same time.

At t8, the control signal Mask changes to HIGH. At the same time, the first divided clock inverted by the switch circuit 6a is input to the input terminal a of the TDC 10. The second divided clock inverted by the switch circuit 6b is input to the input terminal b of the TDC 10.

The VCO 9 keeps on outputting the output clock Fo having a same frequency as that of the output clock Fo at t3 until t8. After t8, the VCO 9 outputs the output clock Fo synchronized with the selected input clock f2. The input clock is changed by the selector 3 when the potential of the node N1 is set substantially constant. Therefore, the output clock Fo is synchronized with the selected input clock f2 without having a disturbance in a waveform of the output clock Fo.

Note that the same explanations could be applied to a case when the SC-signal changes from HIGH to LOW. That is, same explanations could be applied to a case when the clock f1 is selected as the input clock instead of the clock f2. Note that the control signal CCS is changed from HIGH to LOW corresponding to the SC-signal.

In this embodiment, the control signal Mask, which is input to each of the switch circuits 6a and 6b, is set to LOW before the input clock is changed from the clock f1 to the clock f2 by the selector 3. Then, the output signal of the switch circuits 6a and 6b is set to HIGH. The first timing signal and the second timing signal are set to a predetermined voltage level. No phase different current is generated in the charge pump 11. Therefore a fluctuation of a potential at the node N1 is suppressed effectively.

The selector 3 changes the input clock from the clock f1 to the clock f2 while the fluctuation of a potential at the node N1 is suppressed. While the fluctuation of a potential at the node N1 is suppressed, the 1/m divider 4 and the 1/n divider 5 are reset, and the division ratio of the 1/m divider 4 and the 1/n divider 5 are set to a predetermined division ratio corresponding to the clock f2. In this way, the system of the PLL circuit 1 is changed with realizing the VCO 9 being in a self-running state and suppressing the disturbance in the waveform of the output clock Fo. That is, it is possible to change the system of the PLL circuit 1 without stopping or resetting the operation of the PLL circuit 1 and with suppressing the disturbance in the waveform of the output clock Fo.

Note that, resetting the 1/m divider 4 and the 1/n divider 5 is not necessarily performed at the same time with changing the input clock by the selector 3.

### Second Embodiment

Hereinafter, a PLL circuit 30 according to a second embodiment is described. This second embodiment is different from the first embodiment as below. By resetting the TDC 10, the first timing signal and the second timing signal which are output from the TDC 10 are set so as not to generate a current in the charge pump 11.

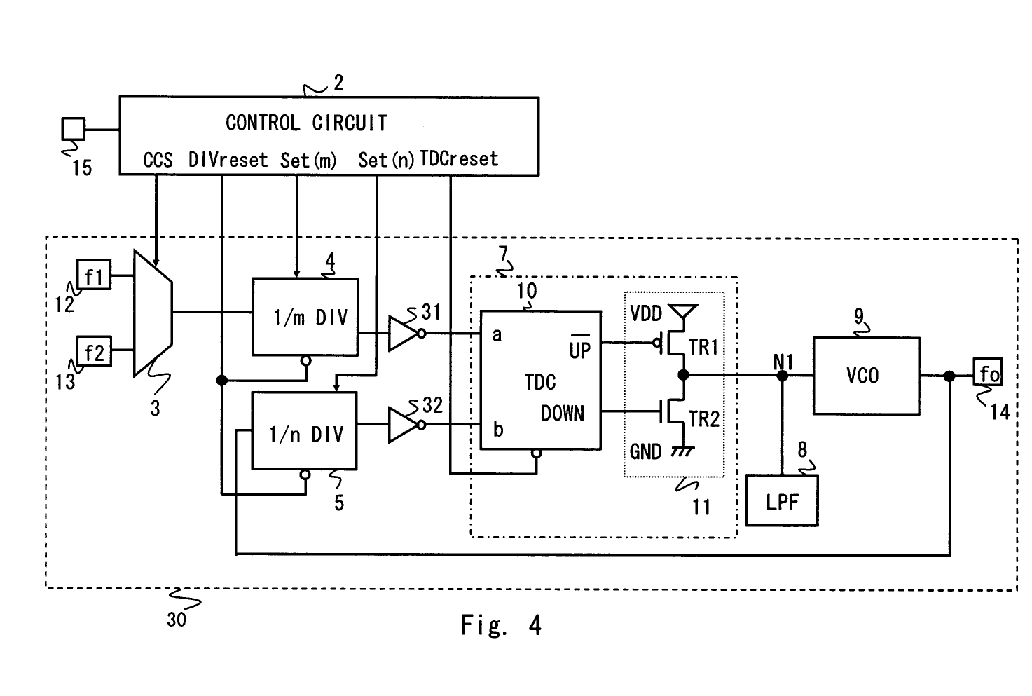

As shown in FIG. 4, the first divided clock divided in frequency by the 1/m divider 4 is inverted by a buffer 31 and input to the input terminal a of the TDC 10. The second divided clock divided in frequency by the 1/n divider 5 is inverted by a buffer 32 and input to the input terminal b of the TDC 10.

The TDC 10 detects a fall in the clock input to the input terminal a and a fall in the clock input to the input terminal b as in the first embodiment. An operation of the charge pump 11, the LPF 8, and the VCO 9 are also the same with those of the first embodiment.

In this embodiment, a control signal TDCreset is input to a reset terminal of the TDC 10 from the control circuit 2. So, the TDC 10 is in a reset-state while the control signal TDCreset is in LOW. While the control signal TDCreset is in LOW, the first timing signal output from the output terminal UP-bar of the TDC 10 is set to HIGH, and the second timing signal output from the output terminal DOWN of the TDC 10 is set to LOW. The TR1 and TR2 are in off-state. So, no current flows from the LPF 8 to the charge pump 11. No current flows from the charge pump 11 to the LPF 8. That is no phase difference current is generated in the charge pump 11. So, a potential of the node N1 is set substantially constant.

Incidentally, the TDC 10 is in a normal operating condition while the control signal TDCreset is in HIGH.

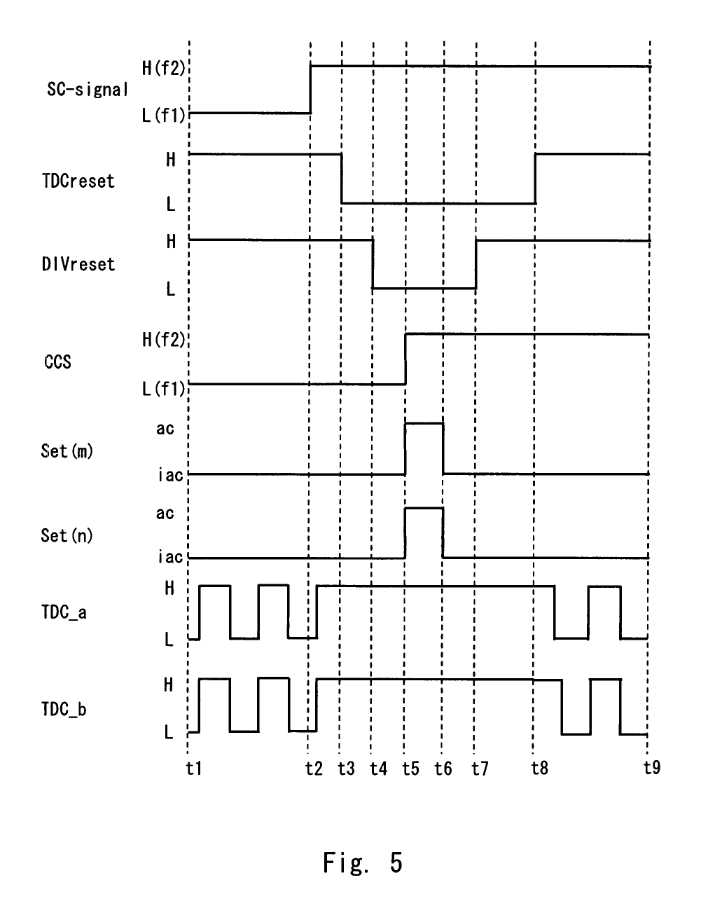

Now, an operation of the PLL circuit 30 is described with reference to a timing chart of FIG. 5.

During a time of t1 to t2, which is the time before the system is changed, the first clock that is divided in frequency by the 1/m divider 4 and inverted by the buffer 31 is input to the input terminal a of the TDC 10. The second clock that is divided in frequency by the 1/n divider 5 and inverted by the buffer 32 is input to the input terminal b of the TDC 10.

At t2, the SC-signal is input to the control circuit 2 via the control terminal 15. The control circuit 2 generates the control signals (CCS, DIVreset, Set(m), Set(n), TDCreset) based on the SC-signal.

At t3, the control signal TDCreset, which is transmitted to the TDC 10 from the control circuit 2, changes to LOW. The output signal from the output terminal UP-bar of the TDC 10 is set HIGH. The output signal from the output terminal DOWN of the TDC 10 is set LOW. The control signal TDCreset is set LOW until t8.

The TDC 10 detects a fall in a clock input to the input terminal a of the TDC 10 and a fall in a clock input to the input terminal b of the TDC 10. The voltage signal output from the output terminal UP-bar (the first timing signal) and the voltage signal output from the output terminal DOWN (the second timing signal) is set constant, as a result of the input voltage input to input terminals a and b of the TDC 10 being set HIGH (substantially constant voltage). That is, a voltage signal output from the output terminal UP-bar is set HIGH, and a voltage signal output from the output terminal DOWN is set LOW. The TR1 and TR2 are in off-state. The VCO 9 continues to output the output clock Fo having a same frequency as that at t3.

An operation of the PLL circuit 1 from t4 to t7 is equal to the first embodiment. So, no more explanation will be made.

At t8, the control signal TDCreset, which is input to the TDC 10 from the control circuit 2, changes to HIGH. Then a clock that is gained by inverting the first divided clock is input to the input terminal a of the TDC 10. A clock that is gained by inverting the second divided clock is input to the input terminal b of the TDC 10.

The VCO 9 continues to output the output clock Fo having a same frequency as that at t3 until t8. After t8, the VCO 9 outputs the output clock Fo synchronized the clock f2. The input clock is changed by the selector 3 while the potential of the node N1 is set substantially constant. So, the output clock Fo is synchronized with the selected new input clock without disturbing a waveform of the output clock Fo.

Note that, same explanations could be applied to a case when the control signal SC-signal is changed to LOW from HIGH. In this case, the control signal CCS is changed to LOW from HIGH corresponding to the control signal SC-signal.

The control signal TDCreset is set LOW, before the system of the PLL circuit 30 is changed. Therefore, the first timing signal and the second timing signal which are output from the TDC 10 are set so as not to generate a phase different current in the charge pump 11. In this way, a fluctuation of a potential level of the node N1 is suppressed effectively.

The selector 3 changes the input clock from the clock f1 to the clock f2 while the fluctuation of a potential at the node N1 is suppressed. While the fluctuation of a potential at the node N1 is suppressed, the 1/m divider 4 and the 1/n divider 5 are reset and the division ratios of the 1/m divider 4 and the 1/n divider 5 are set to a predetermined division ratio corresponding to the clock f2. In this way, the system of the PLL circuit 30 is changed with realizing the VCO 9 being in a self-running state and suppressing the disturbance in the waveform of the output clock Fo. That is, it is possible to change the system of the PLL circuit 30 without stopping or resetting the operation of the PLL circuit 30 and with suppressing the disturbance in the waveform of the output clock Fo.

Note that, resetting the 1/m divider 4 and the 1/n divider 5 is not necessarily preformed at the same time with changing the input clock by the selector 3.

### Third Embodiment

Hereinafter, a PLL circuit 50 according to a third embodiment is described. This third embodiment is different from the first embodiment as below. By setting a 1/m divider 51 and a 1/n divider 52 in a reset-state, voltages input to the input terminals a and b of the TDC 10 are set to HIGH. The first and second timing signals output from the TDC 10 is set so as not to generate any current in the charge pump 11. Further explanation is made below.

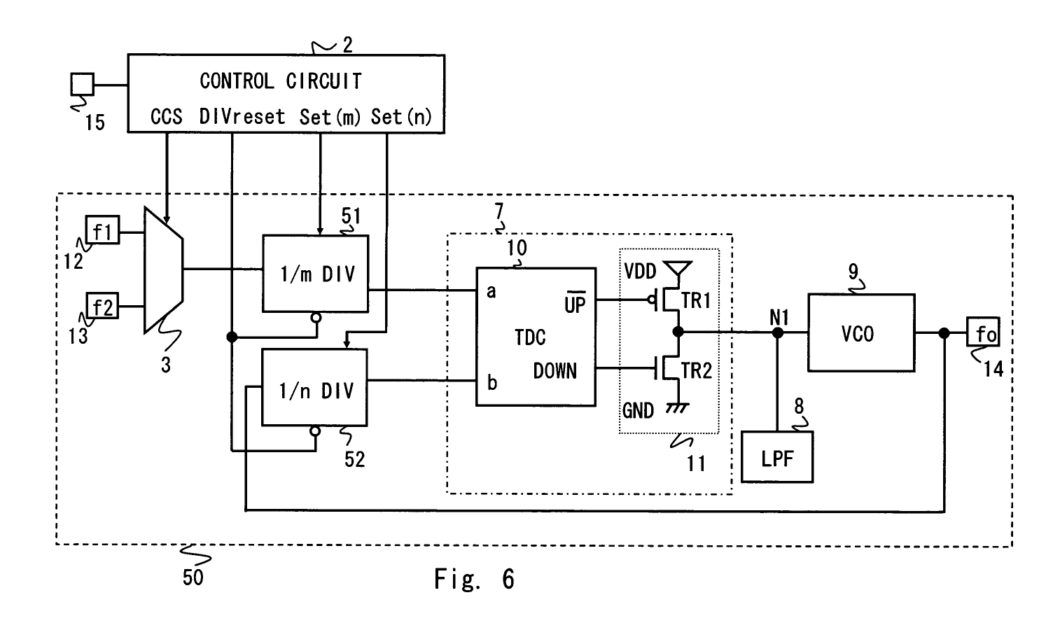

As shown in FIG. 6, the input terminal of the 1/m divider 51 is connected to the output terminal of the selector 3. The output terminal of the 1/m divider 51 is connected to the input terminal a of the TDC 10.

The 1/m divider 51 divides an input clock in frequency and outputs the divided clock after inverting the divided clock. The 1/m divider 51 is configured by the so-called counter.

The division ratio of the 1/m divider 51 is reset by the control signal DIVreset transmitted from the control circuit 2. In this embodiment, an output voltage from the 1/m divider 51 is set HIGH (substantially constant voltage) while the 1/m divider 51 is in reset-state. The division ratio of the 1/m divider 51 is set by the control signal Set(m) from the control circuit 2 as in the first embodiment.

As shown in FIG. 6, the input terminal of the 1/n divider 52 is connected to the output terminal of VCO 9. The output terminal of the 1/n divider 52 is connected to the input terminal b of the TDC 10.

The 1/n divider 52 divides an input clock in frequency and outputs the divided clock after inverting the divided clock. The 1/n divider 52 is configured by the so-called counter.

The division ratio of the 1/n divider 52 is reset by the control signal DIVreset transmitted from the control circuit 2. In this embodiment, an output voltage from the 1/n divider 52 is set HIGH (substantially constant voltage) while the 1/n divider 52 is in reset-state. The division ratio of the 1/n divider 52 is set by the control signal Set(n) from the control circuit 2 as in the first embodiment.

As explained above, in this embodiment, a high-level voltage signal is input to the input terminal a of the TDC 10 from the 1/m divider 51 while the 1/m divider 51 is reset. A high-level voltage signal is input to the input terminal b of the TDC 10 while the 1/n divider 52 is reset.

The TDC 10 detects a fall in the voltage signal input to the input terminal a of the TDC 10, and outputs the first timing signal. The TDC 10 detects a fall in the voltage signal input to the input terminal b of the TDC 10, and outputs the second timing signal.

When the 1/m divider 51 is set to a reset-state, a voltage signal input to the input terminal a of the TDC 10 is set HIGH, and the first timing signal output from the output terminal UP-bar is also set to a predetermined level. In the same way, when the 1/n divider 52 is set to a reset-state, a voltage signal input to the input terminal b of the TDC 10 is set HIGH, and the second timing signal output from the output terminal DOWN is also set to a predetermined level.

That is, the first timing signal is set to HIGH and the second timing signal is set to LOW. The TR1 and TR2 are in off-state. Therefore, no current flows into the LPF 8 from the charge pump 11. No current flows into the charge pump 11 from the LPF 8. In other words, no phase difference current is generated in the charge pump 11. So, a potential of the node N1 is set substantially constant.

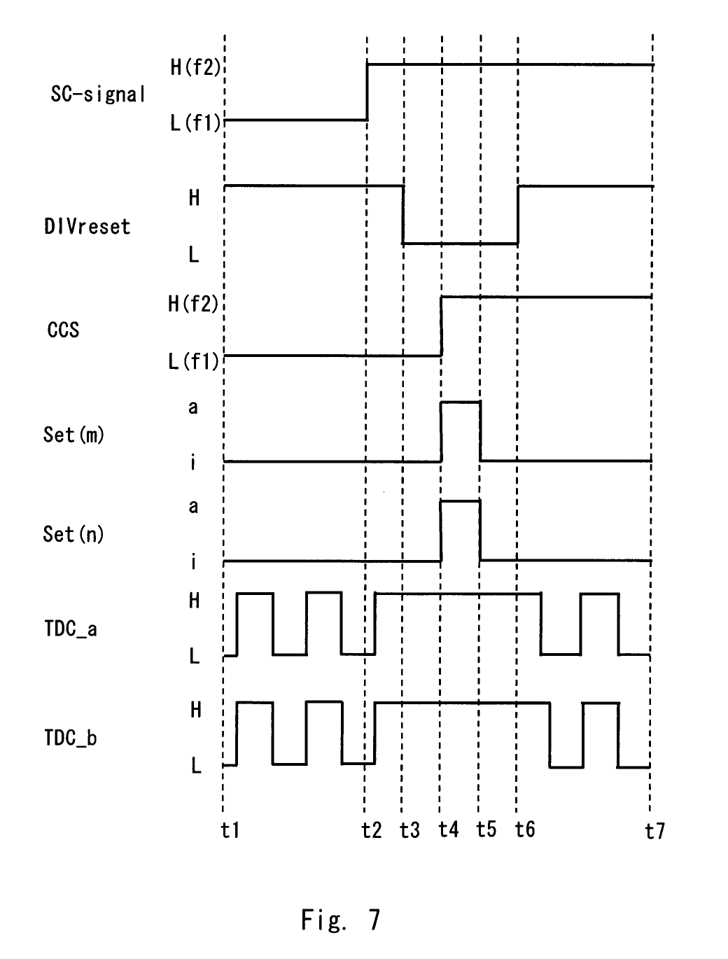

Here, the operation of the PLL circuit 50 is described with reference to the timing chart of FIG. 7.

During the time of t1 to t2, which is the time before a system is changed, the first clock that is divided in frequency and inverted by the 1/m divider 51 is input to the input terminal a of the TDC 10. The second clock that is divided in frequency and inverted by the 1/n divider 52 is input to the input terminal b of the TDC 10.

At t2, the SC-signal is input to the control circuit 2 via the control terminal 15. The control circuit 2 generates the control signals (CCS, DIVreset, Set(m), Set(n)) based on the SC-signal.

At t3, the control signal DIVreset that is input to the 1/m divider 51 and the 1/n divider 52 is changed from HIGH to LOW. The voltage signal output from the 1/m divider 51 is set HIGH. In the same way, the voltage signal output from the 1/n divider 52 is set HIGH.

At this time, the first timing signal output from the output terminal UP-bar is set HIGH. The second timing signal output from the output terminal DOWN is set LOW. The TR1 and the TR2 are in off-state. Therefore, no current flows into the LPF 8 from the charge pump 11. No current flows into the charge pump 11 from the LPF 8. That is, no phase difference current is generated in the charge pump 11. So, a potential of the node N1 is set substantially constant.

The control signal is maintained LOW until t6. Note that, the VCO 9 continues to output the output clock Fo having a same frequency as that at t3.

At t4, the control signal CCS, which is input to the selector 3 from the control circuit 2, is changed from LOW to HIGH as in the first embodiment. Then the selector 3 changes the input clock from the clock f1 to the clock f2, and outputs the clock f2 as an input clock.

At t4, the control signal Set (m) is input to the 1/m divider 51 from the control circuit 2. The control signal Set (m) is used for setting the division ratio of the 1/m divider 51. At t4, the control signal Set(n) is input to the 1/n divider 52 from the control circuit 2. The control signal Set (n) is used for setting the division ratio of the 1/n divider 52. Until t5, the control signal Set(m) and Set(n) are set active-state. After t5, the control signal Set(m) and Set(n) are set inactive-state.

At t6, the control signal DIVreset changes from LOW to HIGH. The 1/m divider 51 and the 1/n divider 52 start to operate for counting. The first clock that is divided in frequency and inverted by the 1/m divider 51 is input to the input terminal a of the TDC 10. The second clock that is divided in frequency and inverted by the 1/n divider 52 is input to the input terminal b of the TDC 10.

The VCO 9 continues to output the output clock Fo having a same frequency as that at t3 until t6. After t6, the VCO 9 outputs the output clock Fo synchronized with the clock f2. The input clock is changed by the selector 3 while the potential of the node N1 is set substantially constant. So, the output clock Fo is synchronized with the selected new input clock without disturbing a waveform of the output clock Fo.

Note that the same explanations could be applied to a case when the control signal SC-signal is changed from HIGH to LOW. In this case, the control signal CCS is changed from HIGH to LOW corresponding to the control signal SC-signal.

The control signal DIVreset is set LOW, before the system of the PLL circuit 50 is changed. Therefore, the voltage signals input to the input terminals a and b of the the TDC 10 are set HIGH. The first and second timing signals are set so as not to generate a phase different current in charge pump 11. In this way, a fluctuation of a potential level of the node N1 is suppressed effectively.

The selector 3 changes the input clock from the clock f1 to the clock f2 while the fluctuation of a potential at the node N1 is suppressed. While the fluctuation of a potential at the node N1 is suppressed, the division ratio of the 1/m divider 51 and the 1/n divider 52 are set to a predetermined division ratio corresponding to the clock f2. In this way, the system of the PLL circuit 50 is changed with realizing the VCO 9 being in a self-running state and suppressing the disturbance in the waveform of the output clock Fo. That is, it is possible to change the system of the PLL circuit 50 without stopping or resetting the operation of the PLL circuit 50 and with suppressing the disturbance in the waveform of the output clock Fo.

Note that resetting the 1/m divider 51 and the 1/n divider 52 is not necessarily preformed at the same time with changing the input clock by the selector 3.

In this embodiment, a potential level of the node N1 is suppressed from fluctuating by setting the 1/m divider 51 and the 1/n divider reset-state which are necessary for a configuration of the PLL circuit 50. So, it is possible to simplify a configuration of the PLL circuit 50 and to shorten a time necessary for changing the system of the PLL circuit 50.

It is apparent that the present invention is not limited to the above embodiments but may be modified and changed without departing from the scope and spirit of the invention. It is possible to adopt other technique for suppressing the fluctuation of the voltage signal input to the VCO 9.

What is claimed is:

1. A phase-locked loop circuit comprising:
a phase detector detecting a phase difference between a first clock and a second clock;
a voltage controlled oscillator outputting the second clock based on an input voltage that fluctuates corresponding to the phase difference detected by the phase detector; and
a selector selecting the first clock from a plurality of clocks based on a clock change signal that is transmitted to the selector while the input voltage is set substantially constant.

2. The phase-locked loop circuit according to claim 1, further comprising:
a control circuit outputting the clock change signal.

3. The phase-locked loop circuit according to claim 2, wherein the control circuit sets the phase detector in a reset-state so as to set the input voltage substantially constant.

4. The phase-locked loop circuit according to claim 2, further comprising:
a first divider connected to a first terminal of the phase detector to divide the first clock in frequency; and
a second divider connected to a second terminal of the phase detector to divide the second clock in frequency.

5. The phase-locked loop circuit according to claim 4, wherein the control circuit sets the first divider and the second divider in a reset-state so as to set the input voltage substantially constant.

6. The phase-locked loop circuit according to claim 4, wherein the phase detector includes:
a timing detection circuit outputting a first timing signal synchronized with a clock output from the first divider and a second timing signal synchronized with a clock output from the second divider; and
a charge pump circuit generating a phase difference current corresponding to a phase difference between the first timing signal and the second timing signal.

7. The phase-locked loop circuit according to claim 6, wherein the control circuit resets the timing detection circuit so as to set the input voltage substantially constant.

8. The phase-locked loop circuit according to claim 6, wherein the control circuit fixes a level of a clock input to a first terminal of the timing detection circuit and a level of a clock input to a second terminal of the timing detection circuit so as to set the input voltage substantially constant.

9. The phase-locked loop circuit according to claim 6, further comprising:
a first switch circuit connected between the first divider and the timing detection circuit;
a second switch circuit connected between the second divider and the timing detection circuit; wherein
the control circuit sets the first and second switch circuits to output a predetermined voltage signal so as to set the input voltage substantially constant.

10. The phase-locked loop circuit according to claim 1, further comprising:
a low-pass filter connected to a node between the phase detector and the voltage controlled oscillator.

11. A phase-locked loop circuit comprising:
a selector selecting a first clock from a plurality of clocks based on a clock change signal;
a first divider dividing the first clock in frequency;
a second divider dividing a second clock in frequency;
a phase detector detecting a phase difference between a clock output from the first divider and a clock output from the second divider;
a voltage controlled oscillator outputting the second clock based on an input voltage that fluctuates corresponding to the phase difference detected by the phase detector; and
a control circuit setting the input voltage substantially constant and outputting the clock change signal while the input voltage is set substantially constant.

12. The phase-locked loop circuit according to claim 11, wherein the control circuit sets the first and second dividers in a reset-state so as to set the input voltage substantially constant.

13. The phase-locked loop circuit according to claim 11, wherein the phase detector comprises:
a timing detection circuit outputting a first timing signal synchronized with the clock output from the first divider and a second timing signal synchronized with the clock output from the second divider; and
a charge pump circuit generating a phase difference current corresponding to a phase difference between the first timing signal and the second timing signal.

14. The phase-locked loop circuit according to claim 13, wherein the control circuit resets the timing detection circuit so as to set the input voltage substantially constant.

15. The phase-locked loop circuit according to claim 11, wherein the control circuit fixes a level of the clock input from the first divider to the timing detection circuit and a level of the clock input from the second divider to the timing detection circuit so as to set the input voltage substantially constant.

16. The phase-locked loop circuit according to claim 11, further comprising:
a first switch circuit outputting a predetermined voltage signal or the clock output from the first divider to the timing detection circuit selectively; and
a second switch circuit outputting a predetermined voltage signal or the clock output from the second divider to the timing detection circuit selectively;
wherein the control circuit sets the first and second switch circuit to output a predetermined voltage signal so as to set the input voltage substantially constant.

17. The phase-locked loop circuit according to claim 11, wherein the timing detection circuit outputs a first timing signal synchronized with a rise or fall of the clock output from a first divider and outputs a second timing signal synchronized with a rise or fall of the clock output from the second divider.

18. The phase-locked loop circuit according to claim 11, further comprising:
a low pass circuit connected to a node between the phase detector and the voltage controlled oscillator.

19. A phase-locked loop circuit comprising:
a phase detector detecting a phase difference between a first clock and a second clock;
a voltage controlled oscillator outputting the second clock based on an input voltage that fluctuates corresponding to the phase difference detected by the phase detector;
a selector selecting the first clock from a plurality of clocks based on a clock change signal; and
means for setting the input voltage substantially constant and for outputting the clock change signal while the input voltage is set substantially constant.
